(19) United States
(12) Patent Application Publication
(10) Pub. No.: US 2004/0164299 A1
(43) Pub. Date: Aug. 26, 2004

(54) Reflective type thin film transistor display device and methods for fabricating the same

(75) Inventors: Yuan-Tung Dai, Chung-Li City (TW); Tsung-Neng Liao, Taichung Hsien (TW); Chun-Chi Lee, Taipei (TW)

Correspondence Address: THOMAS, KAYDEN, HORSTEMEYER & RISLEY, LLP, 100 GALLERIA PARKWAY, NW, STE 1750, ATLANTA, GA, 30339-5948, US

(73) Assignee: Gem Line Technology Co., Ltd., Taichung Hsien (TW)

(21) Appl. No.: 10/373,159

(22) Filed: Feb. 24, 2003

(51) Int. Cl. H01L 29/04

(52) U.S. Cl. 257/72

(57) ABSTRACT

A reflective type thin film transistor display device and methods for fabricating the same is disclosed. The fabrication process includes a first substrate, multiple layers of thin film transistor built on the top layer over the substrate, multiple layers of metal reflector on the periphery of the thin film transistor, and a second substrate, wherein the metal reflector and the thin film transistor are transferred onto the second substrate by a back-end fabrication process to cause the thin film transistor to be exposed on the back end. The metal reflector is formed in between oxide layers and coated with aluminum material on the back side. Since the back side of the reflective display device is not subjected to any etching process or oxidation at high temperature, it is fully flat for a reflective surface after turning over by the back-end fabrication process.

### BACKGROUND OF THE INVENTION

1. Field of the Invention

The present invention relates to the method for fabricating a reflective type thin film transistor display device that is capable of enhancing the reflectivity of the reflective type display device.

2. Description of Related Arts

A reflective type display panels in general is coated with an aluminum layer. The storage capacitor component, as shown in FIG. 4, is used in a dual function reflective display device. The storage capacitor is built on a liquid crystal on silicon (LCOS) backplane, wherein a first polysilicon layer (51) and a second polysilicon layer (53) over a silicon substrate (50) serve as the opposite electrodes of the storage capacitor, and a transparent oxide layer (52) is formed in between the first polysilicon layer (51) and the second polysilicon layer (53) acting as the dielectric for the storage capacitor. A first metal layer (54) overlays the second polysilicon layer (53), and then a first oxide layer (55) covers the storage capacitor. A light absorber (56) and a tungsten plug (57) are respectively formed over the first oxide layer (55), wherein the tungsten plug (57) is connected to the first metal layer (54). A second oxide layer (58) is then formed over the light absorber (56) and the tungsten plug (57). Finally, a metal reflector (59) is formed over the second oxide layer (58) on the top layer of the substrate (50), which is electrically connected to the tungsten plug (57), thus serving both as a reflector and a pixel electrode.

In the fabrication of the reflective type thin film transistor display device, layers of the thin film transistor, the first metal layer (54) and the light absorber (56) are all patterned through thermal budget and dry etching. The lithography process often leaves ripple formation on the processed surface, especially after several times of thermal budget and dry etching. This ripple formation will cause abnormal magnification of the projection beam through the photo mask during patterning of the metal reflector (55), leading to reflector displacement and a bumpy surface on the metal reflector (55). Since aluminum material will tend to deform under high temperature, the reflector displacement is worsened in subsequent press-forming of the optical component over the substrate. The above fabrication process therefore has to be modified in order to enhance the yield rate in the production of reflective type display device.

### SUMMARY OF THE INVENTION

The main object of the present invention is to provide a new reflective type thin film transistor display device and the method for fabricating the same, whereby this reflective display device having a fully flat reflective surface can enhance the reflectivity of the reflective display device, and the reflective display device also possesses the function of a pixel electrode, making it especially suitable for liquid crystal display, OLED or PLED devices.

The reflective type thin film transistor display device in accordance with the present invention comprises:

a first substrate and a second substrate;

multiple layers of thin film transistor, inversely installed on the second substrate after the back-end fabrication process, which is formed by a semiconductor film, a gate insulating layer and a pixel electrode;

multiple transparent electrodes, disposed on the periphery of the thin film transistor on top of the substrate, one end of which is connected to the semiconductor film through a metallizing process;

multiple oxide layers formed under the transparent electrode;

a metal reflector formed in between the transparent electrode and the lower oxide layer; and

a passivation layer for protecting the thin film transistor and the metal reflector.

Since the above mentioned thin film transistor is manufactured in a back-end fabrication process, the transistor is inversely disposed on the backplane. The metal reflector is formed in between the oxide layers and the passivation layer, and so is well protected during the fabrication of the thin film transistor at high temperature. The metal reflector so produced does not have the reflector displacement and ripple formation on the reflective surface, therefore light beams can be more precisely projected on the photo mask during the patterning of the metal reflector. When the substrate is turned over by the back-end fabrication process, the back side not affected by etching processes is fully flat for the reflective surface.

The secondary object of the present invention is to provide a reflective type thin film transistor display device without using a transparent electrode, as the reflective display device also serves as a pixel electrode, making it especially suitable for liquid crystal display, OLED or PLED devices. The basic structure of the reflective display device is identical to that previously described, except that a reflective display device with the function of a pixel electrode is used instead of the transparent electrode. The metal reflector is placed on the top level over the substrate, allowing the metal reflector to be connected to the thin film transistor through a metallizing process. Since the back side of the reflective display device is not damaged to oxidation or etching processes, after the back-end fabrication process, the reflective display device having a fully flat back side surface serves both as a reflector and a pixel electrode,

The features and structure of the present invention will be more clearly understood when taken in conjunction with the accompanying drawings.

### BRIEF DESCRIPTION OF THE DRAWINGS

FIGS. 1A-1D represent the cross-sectional view of a monolithic reflective type thin film transistor display device in accordance with the first embodiment of the invention;

FIG. 2 represents the cross-sectional view of a monolithic reflective type thin film transistor display device in FIG. 1 after the back-end fabrication process;

FIG. 3 represents the cross-sectional view of a monolithic reflective type thin film transistor display device in accordance with the second embodiment of the invention; and

FIG. 4 represents a conventional reflective type thin film transistor display device.

### DETAILED DESCRIPTION OF THE PREFERRED EMBODIMENT

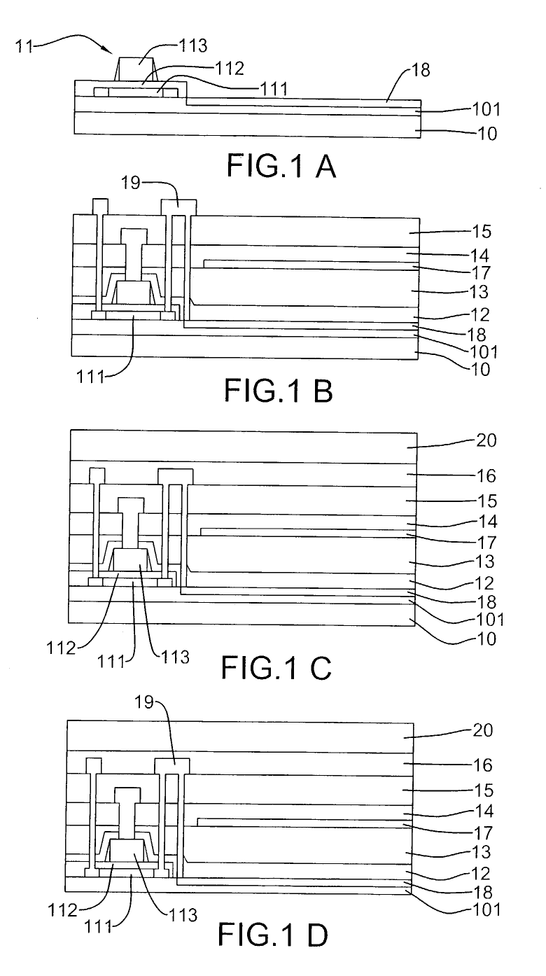

The present invention provides a reflective type thin film transistor display device with superior reflectivity and the method for fabricating the same. The fabrication process as shown in FIGS. 1A-1D, includes the steps of:

providing a first substrate (10) and a second substrate (20);

forming a buffer layer (101) and a thin film transistor (11) over the first substrate (10), wherein the thin film transistor (11) is formed by a semiconductor film (111), a gate insulating layer (112), and a gate electrode (113);

forming a transparent electrode (18) on the periphery of the thin film transistor (11) as shown in FIG. 1A;

forming a first oxide layer (12) over the transparent electrode (18) as shown in FIG. 1B;

forming a second oxide layer (13) over the first oxide layer (12) and the thin film transistor (11) to form a flat surface;

forming a metal reflector (17) over the second oxide layer (13) to correspond to the transparent electrode (18);

forming a third oxide layer (14) over the metal reflector (17) and the second oxide layer (13);

forming a fourth oxide layer (15) over the third oxide layer (14);

electrically connecting the transparent electrode (18) to the semiconductor film (111) of the thin film transistor (11) through a metal layer (19) created in a metallizing process;

forming a protective layer (16) over the fourth oxide layer (15) and the metal layer (19) as shown in FIG. 1C, thus completing the process for fabricating a reflective type thin film transistor display device having a metal reflector;

bonding the second substrate (20) over the protective layer (16), wherein the bonding can be in the form of direct bonding, anode bonding, low temperature bonding, intermediate bonding, adhesive bonding or laser melting;

back-end fabrication process to cause the thin film transistor (11) to be transferred onto the second substrate (20);

removing the first substrate (10) by means of polishing, etching back or by a thermal process with a sacrificial layer (not shown in the diagram) to cause the flat surface of the pixel region to be exposed.

From the foregoing, it is apparent that the thin film transistor (11) is built on the second substrate (20) inversely oriented. Since the metal reflector (17) is formed after the thin film transistor (11) and protected by the oxide layers (12, 13, and 14) and the protective layer (16), it is not affected by etching and oxidation at high temperature in the fabrication of the thin film transistor (11). The metal reflector (17) possesses a flat surface for producing good images, as the reflector displacement problem is controlled to a great extent.

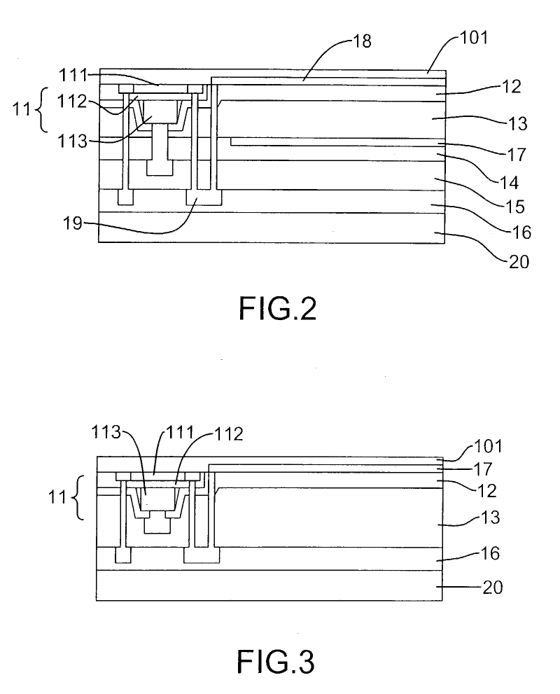

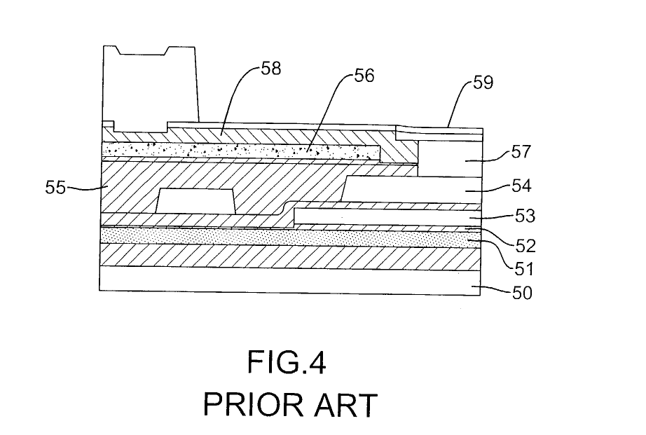

FIG. 2 shows the reflective type thin film transistor display device produced with the above mentioned back-end fabrication process, where the second substrate (20) can be made of silicon, metal, ceramic, sapphire, glass or plastic material.

The thin film transistor (11) is inversely built on top of the second substrate (20), by means of back-end fabrication process, overlaying the fourth oxide layer (15), the semiconductor film (111), the gate insulating layer (112), and the gate electrode (113) in that order.

The transparent electrode (18) is disposed on the periphery of the thin film transistor (11) on top of the second substrate (20), overlaying the oxide layers (12˜15) and the protective layer (16). One end of the transparent electrode (18) is connected to the semiconductor film (111) of the thin film transistor (11) to serve as a pixel electrode.

The metal reflector (17) is disposed in between the second oxide layer (13) and third oxide layer (14), having the reflective surface corresponds to the transparent electrode (18) thereabove.

Since the metal reflector (17) is well protected by the oxide layers (13, 14), it is less likely to be damaged by high temperature oxidation and etching processes. Therefore, the reflector displacement problem will not occur in the subsequent patterning and metallizing processes. A buffer layer (101) is created overlaying the semiconductor film (111) and the transparent electrode (18) to protect the thin film transistor (11) and the transparent electrode (18) in the back-end fabrication process.

FIG. 3 represents the reflective type thin film transistor display device as implemented with the second embodiment of the invention. The reflective display device serves the dual function as a reflector and a pixel electrode. The structure is basically identical to that in the first embodiment, except that the transparent electrode (not shown in the diagram) is not needed. The metal reflector (17) is formed on the top layer over the second substrate (20) and is connected to the semiconductor film (111) through a metallizing process.

In the second embodiment, the metal reflector (17) is disposed in between the second oxide layer (13) and the third oxide layer (14); that means the metal reflector (17) is formed after finishing the third oxide layer (14), the fourth oxide layer (15), and the protective layer (16). During the patterning of the metal reflector (17), the light beam can be precisely projected on the photo mask without causing reflector displacement. The back side of the reflective display device, without being subject to photo irradiation and etching processes, possesses a fully flat surface to serve as the reflector for the reflective display device.

The present invention is advantageous as compared with conventional fabrication processes, in that:

Fully flat reflective surface: although the front side of the reflective display device has undergone etching to remove the photo resist, after the back-end fabrication process the reflective display device is turned over exposing the back side with a fully flat surface.

Enhancing display image: the flat reflector surface also serves as a pixel electrode for liquid crystal display, OLED or PLED devices.

Little oxidation: since the metal reflector is formed in between oxide layers, it can avoid oxidation in high temperature processing.

The foregoing description of the preferred embodiments of the present invention is intended to be illustrative only and, under no circumstances, should the scope of the present invention be so restricted.

What is claimed is:

1. A reflective type thin film transistor display device comprising:
a first substrate and a second substrate;
multiple layers of thin film transistor, which are transferred onto the second substrate after back-end fabrication process, wherein the thin film transistor is made of a semiconductor film, a gate insulating layer, and a gate electrode;
a transparent electrode disposed on the periphery of the thin film transistor and on top layer of the substrate, overlaying multiple oxide layers, wherein one end is connected to the semiconductor film through a metallizing process for establishing electrical connection with the thin film transistor; and
a plurality of layers of metal reflector disposed in between oxide layers below the transparent electrode.

2. The reflective type thin film transistor display device as claimed in claim 1, wherein the transparent electrode is built on the top layer over the substrate.

3. The reflective type thin film transistor display device as claimed in claim 1, the display device further includes a protective layer overlaying the thin film transistor and the transparent electrode.

4. The reflective type thin film transistor display device as claimed in claim 2, the display device further includes a protective layer overlaying the thin film transistor and the transparent electrode.

5. A reflective type thin film transistor display device comprising:
a first substrate and a second substrate;
a plurality of layers of thin film transistor, which are transferred onto the second substrate, wherein the thin film transistor is formed by a semiconductor film, a gate insulating layer, and a gate electrode; and
a plurality of layers of metal reflector, disposed on periphery of the thin film transistor, wherein one end of the metal reflector is connected to the semiconductor film through a metallizing process for establishing electrical connection with the thin film transistor, and the metal reflector is built on top a lower oxide layer.

6. The reflective type thin film transistor display device as claimed in claim 5, wherein the transparent electrode is formed on the top layer over the substrate.

7. The reflective type thin film transistor display device as claimed in claim 5, the display device further includes a protective layer overlaying the thin film transistor and the transparent electrode.

8. The reflective type thin film transistor display device as claimed in claim 6, the display device further includes a protective layer overlaying the thin film transistor and the transparent electrode.

9. A method for fabricating a reflective type thin film transistor display device includes the formation of multiple transparent electrodes on periphery of the thin film transistor, and the formation of a metal reflector on top of lower oxide layer, wherein the surface of the metal reflector that corresponds to the transparent electrodes serves as a reflective surface.

10. The method for fabricating a reflective type thin film transistor display device as claimed in claim 9, wherein the fabrication process in detail includes the steps of:
providing a first substrate and a second substrate;
forming a buffer layer over the first substrate;
forming a thin film transistor over the buffer layer, wherein the thin film transistor is made of a semiconductor film, a gate insulating layer, and a gate electrode;
forming a plurality of transparent electrodes on periphery of the thin film transistor;
forming a first oxide layer over the transparent electrodes and the thin film transistor to provide a flat surface;
forming a plurality of layers of metal reflector over the first oxide layer, wherein the reflective surface corresponds to the transparent electrodes;
forming a second oxide layer over the metal reflector and the first oxide layer;
connecting the transparent electrode to the thin film transistor through a metal layer created by a metallizing process;
forming a protective layer over the second oxide layer and the metal layer;
bonding the second substrate onto the protective layer; and
removing the first substrate to expose the transparent electrode.

11. The method for fabricating a reflective type thin film transistor display device as claimed in claim 10, wherein the buffer layer is partially etched, such that multiple transparent electrodes are respectively formed in slot areas close to the first substrate.

12. The method for fabricating a reflective type thin film transistor display device as claimed in claim 11, wherein the bonding of a second substrate onto the protective layer can be in the form of direct bonding, anode bonding, low temperature bonding, intermediate bonding, adhesive bonding or laser melting;

13. The method for fabricating a reflective type thin film transistor display device as claimed in claim 10, wherein the removal of the first substrate after the back-end fabrication process can be through polishing, etching, or a thermal process with a sacrificial layer.

14. The method for fabricating a reflective type thin film transistor display device as claimed in claim 11, wherein the removal of the first substrate after the back-end fabrication process can be through polishing, etching, or a thermal process with a sacrificial layer.

15. The method for fabricating a reflective type thin film transistor display device as claimed in claim 12, wherein the removal of the first substrate after the back-end fabrication process can be through polishing, etching, or a thermal process with a sacrificial layer.

16. A method for fabricating a reflective type thin film transistor display device includes the formation of a metal reflector on periphery of the thin film transistor, and the connection of the metal reflector to the thin film transistor.

17. The method for fabricating a reflective type thin film transistor display device as claimed in claim 16, wherein the fabrication process in detail includes the steps of:
providing a first substrate and a second substrate;
forming a buffer layer and a thin film transistor over the first substrate, wherein the thin film transistor is formed by a semiconductor film, a gate insulating layer, and a gate electrode;
forming a plurality of layers of metal reflector on periphery of the thin film transistor;
forming an oxide layer over the metal reflector and the thin film transistor;
connecting the metal reflector to the semiconductor film through a metal layer created by a metallizing process;
forming a protective layer over the oxide layer and the metal layer;
bonding the second substrate onto the protective layer; and
removing the first substrate to expose the reflective surface of the reflector.

18. The method for fabricating a reflective type this film transistor display device as claimed in claim 17, wherein the buffer layer is partially etched, such that multiple metal reflectors are respectively formed in slot areas close to the first substrate.

19. The method for fabricating a reflective type thin film transistor display device as claimed in claim 17, wherein the bonding of a second substrate onto the protective layer can be in the form of direct bonding, anode bonding, low temperature bonding, intermediate bonding, adhesive bonding, or laser melting.

20. The method for fabricating a reflective type thin film transistor display device as claimed in claim 18, wherein the removal of the first substrate after the back-end fabrication process can be through polishing, etching, or a thermal process with a sacrificial layer.
